(19) United States
(12) Patent Application Publication
(10) Pub. No.: US 2020/0303016 A1
(43) Pub. Date: Sep. 24, 2020

(54) MEMORY READING METHOD AND MEMORY SYSTEM

(71) Applicant: TOSHIBA MEMORY CORPORATION, Tokyo (JP)

(72) Inventor: Tadashi AMADA, Yokohama Kanagawa (JP)

(21) Appl. No.: 16/557,221

(22) Filed: Aug. 30, 2019

(30) Foreign Application Priority Data
Mar. 20, 2019 (JP) 2019-052956

(51) Int. Cl. G11C 16/26; G06F 3/06; G06F 11/10; G11C 11/56; G11C 16/04; G11C 16/10

(52) U.S. Cl. CPC G11C 16/26; G06F 3/0679; G06F 3/0659; G06F 3/0619; G11C 2211/5644; G11C 11/5642; G11C 11/5628; G11C 16/0483; G11C 16/10; G06F 11/1068

(57) ABSTRACT

A memory reading method includes reading data from a memory cell array of a nonvolatile memory where data is written after randomization, using a first read voltage, counting a total number of bits set to either 1 or 0 in the read data, performing an error correction on the read data, and in case of failure of the error correction, retrying reading the data using a second read voltage only when the counted total number of bits falls within a first predetermined range.

### CROSS-REFERENCE TO RELATED APPLICATION

This application is based upon and claims the benefit of priority from Japanese Patent Application No. 2019-052956, filed Mar. 20, 2019, the entire contents of which are incorporated herein by reference.

### FIELD

Embodiments described herein relate generally to a memory reading method of a nonvolatile NAND flash memory and a memory system.

### BACKGROUND

A memory cell of a NAND flash memory stores data according to an amount of charges stored in the floating gate of each cell transistor. The data read from the memory cell is decoded using an error correction code (ECC) added at a time of writing the data.

### DESCRIPTION OF THE DRAWINGS

FIG. 1 is a functional block diagram of a memory system according to a first embodiment.

FIG. 2 is a circuit diagram of a block BLK0 according to the first embodiment.

FIGS. 3A and 3B are views illustrating examples of distributions of threshold voltages of a cell transistor according to the first embodiment.

FIG. 4 is a flowchart illustrating a write data determination process of the memory system according to the first embodiment.

FIG. 5 is a view illustrating a progress of writing to a plurality of cell transistors MT in a single level cell (SLC) memory according to the first embodiment.

FIG. 6A illustrates an examples of distributions of threshold voltages at 25% write completion to the plurality of cell transistors MT in the SLC memory according to the first embodiment.

FIG. 6B illustrates an example of distributions of threshold voltages at 50% write completion to the plurality of cell transistors MT in the SLC memory according to the first embodiment.

FIG. 6C illustrates an examples of distributions of threshold voltages at 100% write completion to the plurality of cell transistors MT in the SLC memory according to the first embodiment.

FIG. 7 is a diagram illustrating a progress of writing to a plurality of cell transistors MT in a triple level cell (TLC) memory according to the first embodiment.

FIG. 8A illustrates an example of data written for each page of a lower page of the TLC cell transistor according to the first embodiment.

FIG. 8B illustrates an example of data written for each page of a middle page of the TLC cell transistor according to the first embodiment.

FIG. 8C illustrates an example of data written for each page of an upper page of the TLC cell transistor according to the first embodiment.

FIG. 9 is a flowchart illustrating a write data determination process of a memory system according to a second embodiment.

FIG. 10 is a diagram illustrating a change in bit count in a memory system according to a third embodiment.

### DETAILED DESCRIPTION

Embodiments provide a memory reading method and a memory system capable of reducing an amount of processing.

In general, according to one embodiment, a memory reading method includes reading data from a memory cell array of a nonvolatile memory where data is written after randomization, using a first read voltage, counting a total number of bits set to either 1 or 0 in the read data, performing an error correction on the read data, and in case of failure of the error correction, retrying reading the data using a second read voltage only when the counted total number of bits falls within a first predetermined range.

Hereinafter, a memory reading method and a memory system of embodiments will be described in detail with reference to drawings.

The drawings are schematic drawings. In the following description, elements having the same function and configuration are denoted by the same reference numerals. The alphabet after the reference, the numerals making up the sign, is referred to by the reference numeral containing the same numeral. It is used in order to distinguish the elements which have similar configurations. It is not necessary to distinguish between elements indicated by reference numerals that include the same numeral. In this case, these elements are referenced by reference numerals including only numbers.

### First Embodiment

### Confirmation of Memory System

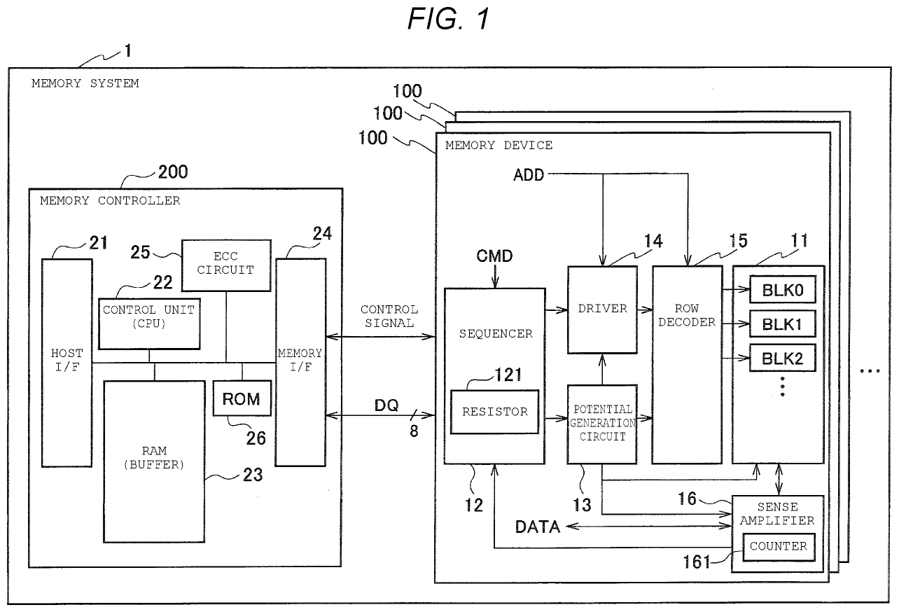

FIG. 1 is a functional block diagram of a memory system according to a first embodiment. A memory system 1 is a storage device configured to communicate with a host device (not illustrated). The memory system 1 stores data from the host device according to an instruction transmitted from the host device.

The memory system 1 includes a plurality of memory devices 100 and a memory controller 200. The memory system 1 is, for example, a memory card such as an SD™ card or a solid state device (SSD). The memory device 100 and the memory controller 200 may be formed on chips sealed with a resin, for example, in separate packages. The memory device 100 and the memory controller 200 may be formed on one chip.

The plurality of memory devices 100 have the same elements and connections. Here, one memory device 100 will be described as a representative. The description of one memory device 100 applies to other memory devices 100. The memory device 100 is a NAND flash memory that stores data in a non-volatile manner.

### Configuration of Memory Controller

The memory controller 200 responds to the instruction from the host device. The memory controller 200 is a control device that instructs the memory device 100 to read, write, or erase data. The memory controller 200 writes the data instructed to be written by the host device in the memory device 100. The memory controller 200 reads from the memory device 100 the data instructed to be read from the host device. The memory controller 200 transmits the data read from the memory device 100 to the host device.

In addition, the memory controller 200 also manages a memory space in the memory device 100. For example, the memory controller 200 manages an address and a state of the memory device 100. The memory controller 200 maintains a mapping of logical addresses and physical addresses. A physical address specifies a physical memory area in the memory device 100. The mapping of the logical addresses and the physical addresses is stored in an address conversion table, and is refereed to when a logical address is specified as a destination of data to be written.

The memory controller 200 obtains the physical address associated with a certain logical address and reads data from a memory area specified by the obtained physical address. The management of the state of the memory device 100 includes management of the memory area of the memory device 100, management of degree of wear-out, garbage collection or compaction, and refresh.

The memory controller 200 includes a host interface 21, a control unit 22, a random access memory (RAM) 23, a memory interface 24, an ECC circuit 25, and a read only memory (ROM) 26. In each drawing, the interface is illustrated as I/F.

For example, the control unit 22 is a central processing unit (CPU) configured to execute a firmware or a program stored in the ROM 26 and loaded onto the RAM 23 to achieve a part or all of functions of the memory controller 200. The host interface 21, the control unit 22, the RAM 23, the memory interface 24, the ECC circuit 25, and the ROM 26 are mutually connected by a bus.

The host interface 21 is a hardware interface that communicates with an external device such as a host device. For example, the host interface 21 transfers an instruction and data received from the host device to the control unit 22 and the RAM 23.

The RAM 23 is a memory which temporarily stores data received by the memory controller 200 from the memory device 100 and the host device, and operates as a buffer.

The memory interface 24 is a hardware interface connected to the memory device 100 and performing communication between the memory controller 200 and the memory device 100. The memory interface 24 transmits and receives signals according to NAND interface standards, which define requirements for control signals and input and output signals DQ. The input and output signals DQ (DQ0 to DQ7) have an 8-bit width, for example, and include a command (CMD), write data and read data (DATA), an address signal (ADD), and various management data.

The ECC circuit 25 is a hardware circuit that performs data error correction. The ECC circuit 25 is connected to the memory device 100 via the memory interface 24. Specifically, the ECC circuit 25 generates parity when data is written to the memory device 100. When the data is retrieved, the ECC circuit 25 generates a syndrome from the parity, detects an error, and corrects the detected error.

In addition, the ECC circuit 25 performs an error checking and correction operation on the data read from the memory device 100. The ECC circuit 25 restores correct data from the read data if the code error of the read data is within the error checking and correction ability. The error checking and correction ability is determined based on the error checking and correction data included in the read data. The ECC circuit 25 cannot restore the correct data from the read data if the error in the read data exceeds the error checking and correction ability.

The control unit 22 is an arithmetic processing unit. The control unit 22 is connected to the host interface 21, the RAM 23, the memory interface 24, the ECC circuit 25, and the ROM 26 and access or control these components by executing a program. The control unit 22 manages the state of the memory device 100 via the memory interface 24 at the time of writing and reading. In addition, the control unit 22 issues a write, read, or erase command in response to the write, read, or erase command received from the host device.

The overall control unit 22 converts each value in units of bits with an equal probability to 0 or 1 independently of bits before writing data to the memory device 100 before parity generation by the ECC circuit 25. This process is called randomization. As a result of randomization, the numbers of 0 or 1 of the data to be written are about the same (i.e., 50%, respectively).

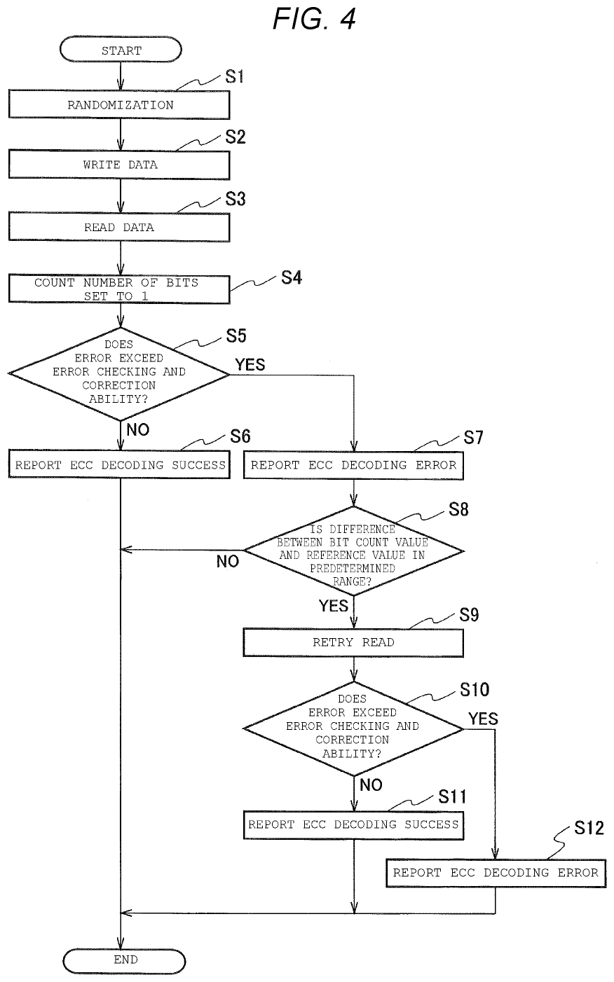

The ROM 26 is a memory from which data can only be read. The ROM 26 is connected to the control unit 22. The ROM 26 stores a write data determination processing program. The control unit 22 executes the processes of the flowchart illustrated in FIG. 4 by executing the write data determination processing program stored in the ROM 26.

### Configuration of Memory Device

Each memory device 100 includes a memory cell array 11, a sequencer 12, a voltage generation circuit 13, a driver 14, a row decoder 15, a sense amplifier 16, and the like.

The memory cell array 11 is a memory unit including a plurality of blocks BLK (BLK0, BLK1, . . . ). The memory cell array 11 is connected to the voltage generation circuit 13, the row decoder 15, and the sense amplifier 16. The data in each block BLK is erased at once. Each block BLK includes a plurality of cell transistors (i.e., memory cells) associated with bit lines and word lines. The cell transistor stores data written by the memory controller 200 in a non-volatile manner.

The voltage generation circuit 13 is a hardware circuit that generates a voltage. The voltage generation circuit 13 is connected to the sequencer 12, the memory cell array 11, the driver 14, the row decoder 15, and the sense amplifier 16. The voltage generation circuit 13 generates a voltage based on an instruction of the sequencer 12. The generated voltage is supplied to the memory cell array 11, the driver 14, the row decoder 15, and the sense amplifier 16. The driver 14 receives an address signal ADD from the memory controller 200, selects some of the voltages from the voltage generation circuit 13 based on the address signal ADD, and supplies the selected voltage to the row decoder 15.

The row decoder 15 is a hardware circuit that decodes a block address or a page address. The row decoder 15 is connected to the memory controller 200. The row decoder 15 receives the address signal ADD from the memory controller 200. The row decoder 15 selects one block based on the address signal ADD. The row decoder 15 applies the voltage generated by the driver 14 to the selected block BLK. In addition, the row decoder 15 selects a word line corresponding to a cell transistor to be subjected to the read operation and the write operation. The row decoder 15 applies desired voltages to the selected word line and the non-selected word line, respectively.

The sense amplifier 16 is a circuit that amplifies the voltage from the memory cell. When reading data, the voltage read from the memory cell to the bit line is as small as several hundred mV. The sense amplifier 16 amplifies a voltage fluctuation of the bit line to a level at which it can be handled as a digital signal when reading the data. In addition, the sense amplifier 16 also includes a counter 161. The counter 161 counts the number of bits set to either 1 or 0 in the read data, and transfers the count result to the sequencer 12.

The sequencer 12 is a controller or a control circuit that controls the operation of the memory device 100. The sequencer 12 is connected to the memory controller 200. The sequencer 12 controls the voltage generation circuit 13, the driver 14, the sense amplifier 16, and the like based on a command CMD from the memory controller 200. The sequencer 12 includes a register 121. The register 121 includes a plurality of memory areas. Each memory area is specified by a unique address, and stores one or a plurality of bits of information. The register 121 stores various data in each memory area.

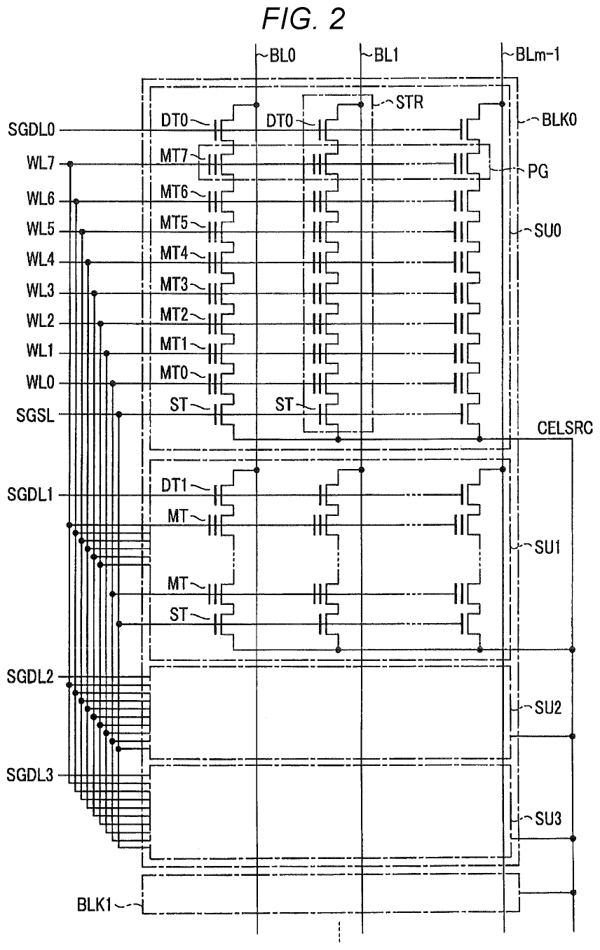

FIG. 2 is a circuit diagram of a block BLK0 according to the first embodiment. FIG. 2 illustrates the elements and connections of a block BLK0 of the memory cell array 11. The other blocks BLK other than the block BLK0 have the same elements and connections as the block BLK0 illustrated in FIG. 2.

The block BLK0 includes a plurality of transistors associated with bit lines and word lines. The block BLK0 is formed of a plurality of string units SU (e.g., SU0 to SU3). Each string STR includes one select gate transistor ST, a plurality of cell transistors MT (e.g., MT0 to MT7), and one select gate transistor DT (e.g., DT0 to DT3). In the block BLK0, each of m (m is a natural number) bit lines BL0 to BLm−1 is connected to one string STR of each of four string units SU0 to SU3.

The control gate electrode of one select gate transistor ST is connected to a signal line SGSL. The control gate electrodes of the plurality of cell transistors MT (i.e., MT0 to MT7) are connected to a word line WL. The control gate electrode of one select gate transistor DT (e.g., DT0 to DT3) is connected to the signal line SGDL0. The select gate transistor ST, the cell transistor MT, and the select gate transistor DT are connected in series to a source line CELSRC and one bit line BL in this order.

The cell transistor MT is a metal oxide semiconductor field effect transistor (MOSFET). The control gate electrode of the cell transistor MT is connected to the word line WL. The cell transistor MT includes a control gate electrode and a floating gate electrode isolated from the surroundings. In the cell transistor MT, the threshold voltage changes in accordance with an amount of charge stored in the floating gate electrode. That is, the cell transistor MT stores data according to the amount of charge. At the time of data writing, the cell transistor MT injects electrons into the floating gate electrode. At the time of data erasing, the cell transistor MT extracts the electrons from the floating gate electrode.

The plurality of strings STR connected to the plurality of bit lines BL forma plurality of string units SU (i.e., SU0, SU1, SU2, and SU3). Each string unit SU includes the string STR connected to each bit line BL.

In each string unit SU, the control gate electrodes of the cell transistors MT (i.e., MT0 to MT7) are connected to word lines WL0 to WL7, respectively. Furthermore, the word lines WL of the same address in different string units SU are also mutually connected.

A set of cell transistors MT sharing the word line WL in one string unit SU is treated as one page PG, and data writing and reading are performed page by page. That is, the cell transistors MT of one page PG are collectively written with data, and are collectively read with data. The page PG may be managed collectively.

Select gate transistors DT0 to DT3 belong to string units SU0 to SU3, respectively. For each a (a is 0 or a natural number less than 3), the gate of a select gate transistor DTa of each of the plurality of strings STR of the string unit SUa is connected to a select gate line SGDLa. The gate of the select gate transistor ST is connected to a select gate line SGSL.

The memory device 100 stores data of one or more bits in one cell transistor MT. A cell for storing one bit of data per cell transistor as a result of writing is called SLC. The amount of charge stored in the cell transistor MT, which is SLC, is classified into two levels. A cell for storing 2 bits of data per 1 cell transistor is called a multi-level cell (MLC). The amount of charge stored in the cell transistor MT, which is an MLC, is classified into four levels. A cell for storing data of 3 bits per 1 cell transistor is a called a triple level cell (TLC). The cell transistor MT, which is TLC, is classified into eight levels of charge accumulation. As the number of bits per one cell transistor increases, the memory element has a larger data capacity.

The output of the voltage generation circuit 13 is connected to each of the word lines WL0 to WL7 and the sense amplifier 16 is connected to each of the bit lines BL0 to BLm−1. One of the word lines WL0 to WL7 is selected, and the word line selected by the voltage generation circuit 13 is set to an off-voltage of the cell transistor MT and the other word lines are set to an on-voltage. By sensing the voltages of the bit lines BL0 to BLm−1 by the sense amplifier 16, data of one page can be read.

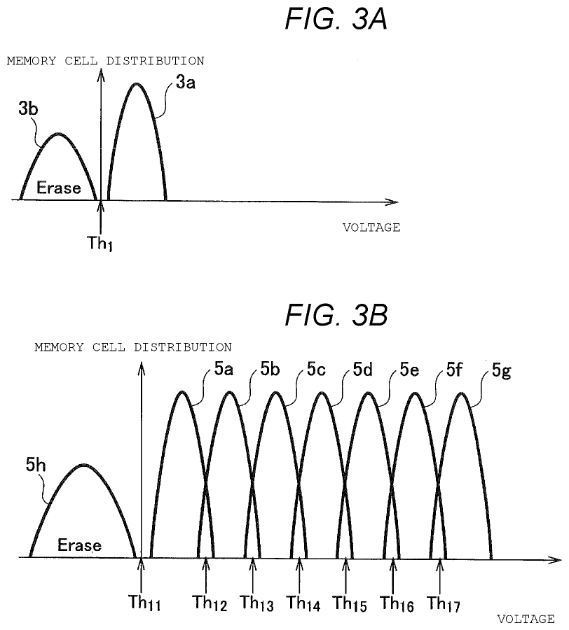

FIGS. 3A and 3B are views illustrating examples of distributions of threshold voltages of a cell transistor according to the first embodiment. FIG. 3A illustrates an example of a distribution of the threshold voltages of a plurality of cell transistors MT which are SLCs. FIG. 3B illustrates an example of the distribution of the threshold voltages of the plurality of cell transistors MT which are TLCs. In FIG. 3A and FIG. 3B, a vertical axis represents the number of cell transistors MT, and a horizontal axis represents the threshold voltage.

In FIG. 3A, the distribution 3b schematically illustrates the distribution of a plurality of cell transistors in an erased state (also referred to as an erase state or an Er state) in which the threshold voltage is less than or equal to a read voltage Th₁. The data writing is executed on the cell transistor MT in the Er state. The distribution 3a schematically illustrates a distribution of a plurality of cell transistors in an “A state” in which the threshold voltage is Th₁ or more. The read voltage Th₁ in the cell transistor MT which is SLC is, for example, 0V. As a result of the writing, the cell transistor MT which is SLC transitions from the Er state to the A state.

In FIG. 3B, a plurality of read voltages Th including seven read voltages Th₁₁ to Th₁₇ is set. The threshold voltages of the cell transistor MT are grouped by these read voltages Th₁₁ to Th₁₇ (i.e., 5a-5g). That is, the data is read using the read voltages Th₁₁ to Th₁₇. A distribution 5h indicates the distribution of the erased state.

### Write Data Determination Process

Next, a write data determination process of the memory system of the first embodiment will be described. FIG. 4 is a flowchart illustrating a write data determination process of a memory system according to the first embodiment. The write data determination process will be described with reference to FIG. 4.

When receiving a write instruction from the host device, the control unit 22 selects the memory device 100 to which data is to be written. The control unit 22 converts each value in units of bits independently to 0 or 1 with equal probability before writing data (step S1). The number of 0 or 1 of data to be written is about the same number (i.e., 50%). The control unit 22 instructs the selected memory device 100 to write the data (step S2). The write instruction received from the host device includes, for example, a signal specifying a page, data, an address signal, and a write execution command. Next, the sequencer 12 writes the data in the cell unit according to the instruction from the control unit 22.

Here, if unexpected power loss (e.g., system shutdown) occurs during the write operation, some of the cell transistors into which data should be written remain in the Er state, as shown in FIG. 3. That is, the ratio of 0 or 1 bit data in the target page of the write operation may not be 50%.

Next, the control unit 22 transmits a read signal to the memory device 100 selected in step S2. The control unit 22 executes a data read process on the memory device 100 selected in step S2 (step S3). The sequencer 12 reads data of the read target page.

The control unit 22 causes the counter 161 to count the number of bits set to either 1 or 0 in binary data obtained at the time of data reading in S3 (step S4). The counter 161 transfers the bit count value to the sequencer 12. The sequencer 12 sends the bit count value to the control unit 22.

The control unit 22 causes the ECC circuit 25 to perform the error checking and correction operation on the binary data obtained at the time of the data read of S3 (step S5). If the error in the read data is within the error checking and correction ability (No in step S5), the ECC circuit 25 reports the control unit 22 that the correct data can be restored from the read data (i.e., ECC decoding success) (step S6). When the ECC decoding success is reported from the ECC circuit 25, the control unit 22 ends the series of processes. If the error in the read data exceeds the error checking and correction ability (YES in step S5), the ECC circuit 25 reports the control unit 22 that the correct data cannot be restored from the read data (i.e., ECC decoding error) (step S7).

When the ECC circuit 25 is reported of the ECC decoding error, the control unit 22 determines whether a difference between the bit count value counted in S4 and a reference value is within a predetermined range (step S8).

If it is determined that the difference between the bit count value and the first reference value is within a predetermined range (Yes in step S8), the control unit 22 performs retry read at a read voltage different from at the time of the data read in S3 (step S9). If it is determined that the difference between the bit count value and the first reference value is not within the predetermined range (No in step S8), the control unit 22 ends the series of processes.

The control unit 22 causes the ECC circuit 25 to perform an error checking and correction operation on the binary data obtained at the time of the retry read in S9 (step S10). If the error of the read data is within the error checking and correction ability (No in step S10), the ECC circuit 25 reports the control unit 22 that the correct data can be restored from the read data (i.e., ECC decoding success) (step S11). When the ECC decoding success is reported from the ECC circuit 25, the control unit 22 ends the series of processes. If the error in the read data exceeds the error checking and correction ability (YES in step S10), the ECC circuit 25 reports the control unit 22 that the correct data cannot be restored from the read data (i.e., ECC decoding error) (step S12). When the ECC decoding success is reported from the ECC circuit 25, the control unit 22 ends the series of processes.

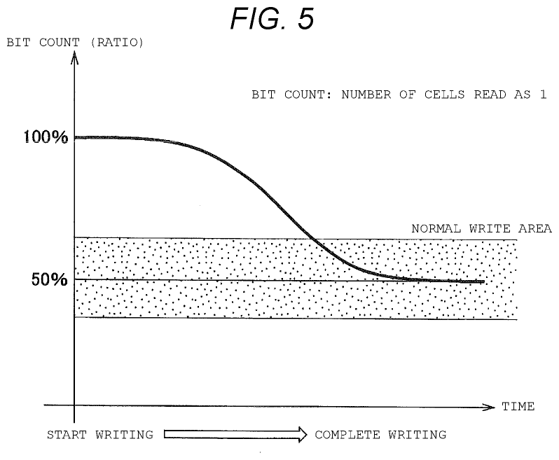

FIG. 5 is a view illustrating a progress of writing to a plurality of cell transistors MT in the SLC memory according to the first embodiment. The horizontal axis indicates a time from a start of the writing to a predetermined number of cell transistors MT to a completion of the writing. The vertical axis represents a bit count (or ratio) of “1” in binary data obtained at the time of data reading from the predetermined number of cell transistors MT. The predetermined number is, for example, one page. As shown in FIG. 5, when the bit count (e.g., the number of cells maintaining data “1”) reaches about 50% (e.g., the normal write area), the write operation is considered as being done.

At the start of writing, all data are 1. As described above, since the data to be written to the cell transistor MT is randomized, the bit count is 50% when the writing is completed.

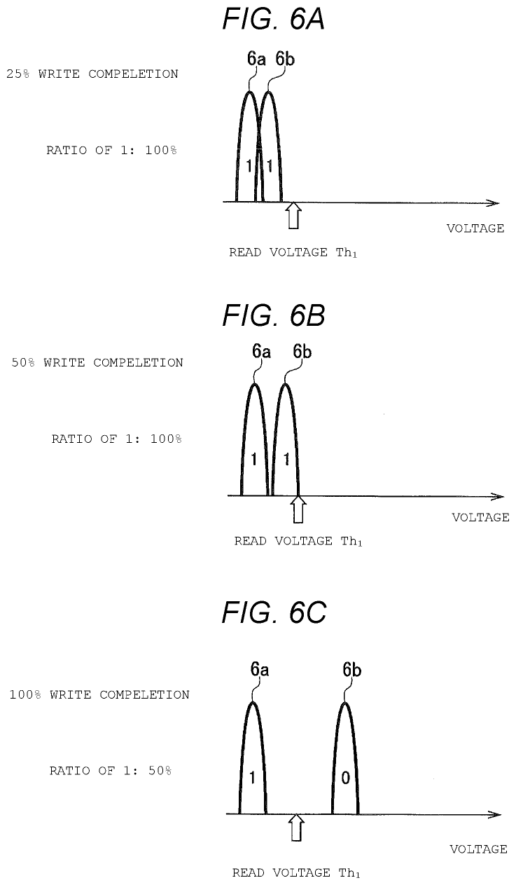

FIGS. 6A to 6C illustrate examples of distributions of threshold voltages at 25% write completion, 50% write completion, and 100% write completion to a plurality of cell transistors MT as SLC according to the first embodiment. A process of changing the bit count (or ratio) as illustrated in FIG. 5 will be described with reference to FIGS. 6A to 6C.

As illustrated in FIG. 6A, when writing is completed 25%, it is considered that data writing progresses 25% to the whole half of the cell transistors MT by randomization. However, at around 25%, the threshold voltage does not exceed the read voltage, and the ratio of 1 of written data is considered to be 100%. Next, as illustrated in FIG. 6B, it is considered that when writing is completed 50%, data writing progresses 50% to the whole half of the cell transistors MT. However, even at 50%, the threshold voltage does not exceed the read voltage, and the ratio of 1 of written data is considered to be 100%. Next, as illustrated in FIG. 6C, when the writing 100% is completed, it is considered that data writing progresses 100% to the whole half of the cell transistors MT. If progressing to 100%, the threshold voltage exceeds the read voltage, and the ratio of 1 of written data is considered to be 50%.

In FIGS. 6A to 6C, the control unit 22 determines that the data can be read when the ratio of 1 falls below a reference value, for example, 60%. This state is called an assignment state where data reading including retry reading is possible, including a state where writing is not completely completed, for example, 99% writing is also completed.

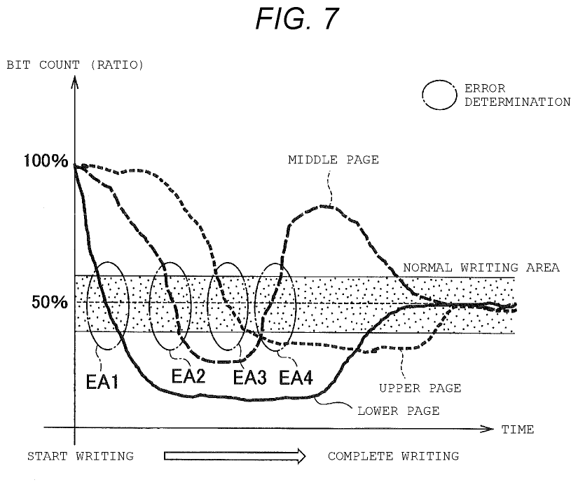

Next, the case where data is written to a plurality of pages in a TLC memory will be described. FIG. 7 is a diagram illustrating a progress of writing to a plurality of cell transistors MT in the TLC memory according to the first embodiment. The horizontal axis indicates the time from the start of the writing to a predetermined number of cell transistors MT to the completion of the writing. The vertical axis represents the bit count or ratio of 1 in binary number data obtained at the time of data reading from a predetermined number of cell transistors MT. The predetermined number is, for example, one page. The vertical axis represents the change in the bit count value from the start of the writing to the upper page, the middle page, and the lower page to the completion of writing. In FIG. 7, when the bit count largely deviates from 50%, the control unit 22 determines that the data cannot be read.

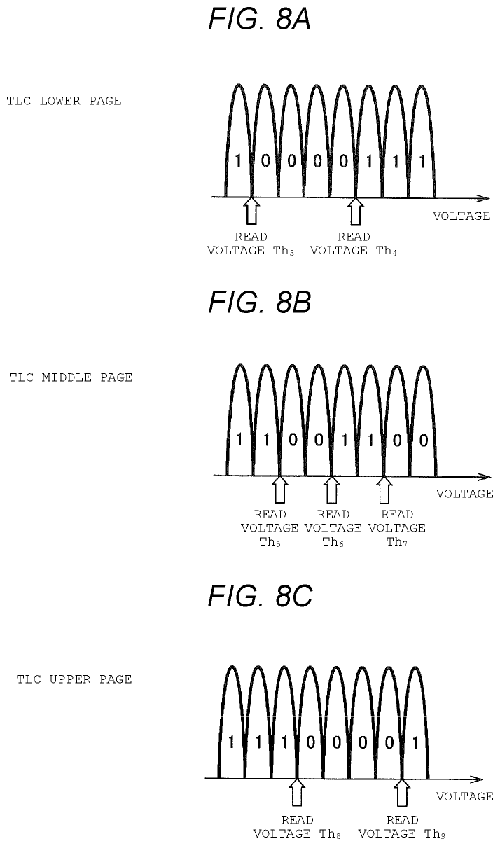

FIGS. 8A to 8C are diagrams illustrating examples of data written for each page of a lower page, a middle page, and an upper page of the TLC cell transistor according to the first embodiment.

In the lower page illustrated in FIG. 8A, eight levels of TLC are defined as 10000111 from the lowest threshold voltage order, and the threshold voltages Th₃ and Th₄ are set such that “1” is read when the read voltage is less than Th₃ or is equal to or greater than Th₄, and “0” is read when the voltage is equal to or greater than Th₃ but less than Th₄. In the middle page illustrated in FIG. 8B, eight levels of TLC are defined as 11001100 from the lowest threshold voltage order, and the threshold voltages Th₅, Th₆, and Th₇ are set such that “1” is read when the read voltage is less than Th₅, or is equal to or greater than Th₆ but less than Th₇, and “0” is read when the read voltage is equal to or greater than Th₅ but less than Th₆ or is equal to or greater than Th₇.

In the upper page illustrated in FIG. 8C, eight levels of TLC are defined as 11100001 from the lowest threshold voltage order, and the threshold voltages Th₈ and Th₉ are set such that “1” is read when the read voltage is less than Th₈ or is equal to or greater than Th₉, and “0” is read when the read voltage is equal to or greater than Th₈ but less than Th₉. The memory controller 200 reads data using seven read voltages Th₃ to Th₉. The method of setting the TLC read voltage may be a method other than the above method as long as it can distinguish 3 bits.

In the memory cell transistors MT of the distribution labelled “1”, the floating gate electrode does not have electrons. In the memory cell transistors MT of the distribution labelled “0,” the floating gate electrode has electrons. At the start of writing, all data in the memory cell transistors MT are 1, and thus the ratio of 1 is 100%. As described above, since the data to be written to the cell transistor MT is randomized, the bit count is 50% when the writing is completed. In the erased state, the ratio of 1 is 100% for each page of the upper page, the middle page, and the lower page.

In FIG. 7, in areas EA1, EA2, EA3, and EA4 shown by dotted lines, the bit count is around 50% even though writing is not completed. Thus, the writing state may be erroneously determined. In second and third embodiments, memory systems that prevent such erroneous determination are provided.

As described above, according to the memory system of the first embodiment, when the data is read, the number of bits set to 1 or 0 included in the data (i.e., bit count value) is counted. If a decoding error occurs in the read data, it is determined, based on the bit count value and the first reference value, whether complete writing is performed. If it is determined that complete writing is performed, the retry reading is performed.

That is, the state of the written data is determined based on the ratio of the number of bits of 0 and 1 of the data obtained at the time of read, and the retry reading is performed when complete writing is performed.

Accordingly, the retry read can be avoided when data writing is incomplete. In addition, even for the normal write data, it is possible to avoid an extra read by the assigned check.

### Second Embodiment

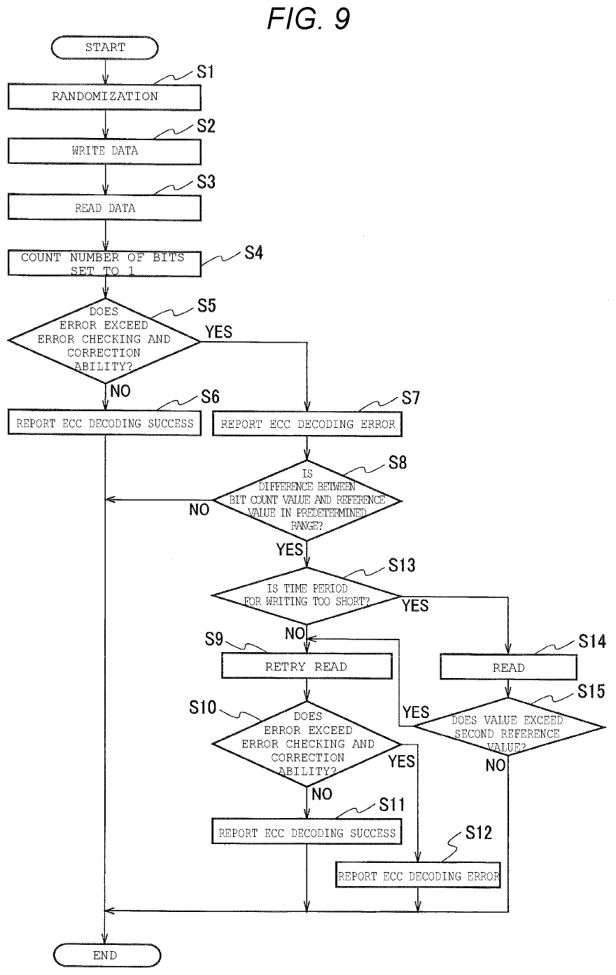

In the memory system of the second embodiment, in addition to the write data determination process of the memory system of the first embodiment, an assigned check determination is added to prevent the erroneous determination discussed above. FIG. 9 is a flowchart illustrating the write data determination process of the memory system according to the second embodiment. Each process of the flowchart illustrated in FIG. 9 is executed by the control unit 22 executing the write data determination processing program stored in the ROM 26.

Next, the retry read operation of the memory system of the second embodiment will be described with reference to the flowchart of FIG. 9. First, since the processes of steps S1 to S12 are the same as the processes of the flowchart of FIG. 4, the description thereof is omitted here.

If it is determined that the difference between the bit count value and the first reference value is within the predetermined range (YES in step S8), the control unit 22 determines whether the time period for writing is too short such that the writing of data in a plurality of pages may not have completed (step S13). If it is determined that the difference between the bit count value and the first reference value is not within the predetermined range (No in step S8), the control unit 22 ends the series of processes.

If the control unit 22 determines that the time period for writing is not too short so the writing of data in a plurality of pages may have completed in step S13 (No in step S13), retry reading is performed (step S9). If it is determined that the time period for writing is too short such that the writing of data in a plurality of pages may not have completed (YES in step S13), reading is performed (step S14). For example, the time period for writing is determined to be too short when an elapsed time since the start of the data writing does not exceed a predetermined time.

The control unit 22 determines whether the number of bits of 0 exceeds the second reference value for the data read in step S14 (step S15). If it is determined that the number of bits of 0 exceeds the second reference value (YES in step S15), the process proceeds to step S9, and the control unit 22 executes the retry reading of data (step S9).

If it is determined that the number of bits of 0 does not reach the second reference value (No in step S15), the control unit 22 ends the series of processes in FIG. 9 (end).

As described above, according to the memory system of the second embodiment, it is possible to prevent erroneous determination which may happen when data writing is incomplete. In addition, the retry reading is not performed when data writing is incomplete.

### Third Embodiment

In the memory system of the third embodiment, in addition to the write data determination process of the memory system of the first embodiment, a determination process based on a combination of a plurality of pages is added to prevent erroneously determination about the writing state.

In the memory system according to the third embodiment, the control unit 22 determines whether the data is incompletely written data based on the bit count value from the start to the completion of writing to the upper page and the lower page.

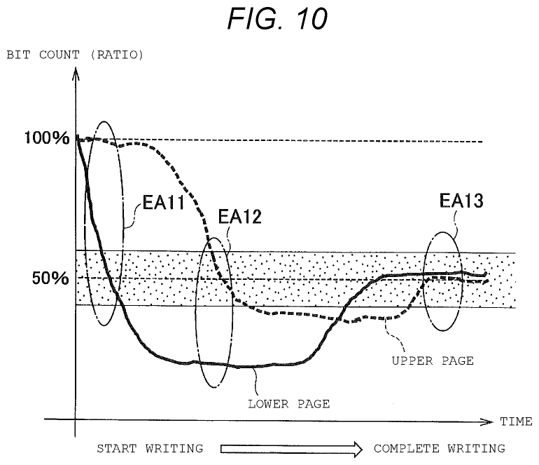

FIG. 10 is a diagram illustrating a change in bit count in the memory system according to the third embodiment.

The operation of the control unit 22 will be described with reference to FIG. 10. As illustrated in FIG. 10, immediately after the start of writing, the upper page bit count is about 100%, and the lower page bit count is about 50% (area EA11).

The difference between the upper page bit count and the lower page bit count is 50%. When the bit count difference exceeds, for example, 20%, the control unit 22 determines that the data is incompletely written data.

Next, during the writing, the upper page bit count is about 50%, and the lower page bit count is about 20% (area EA12).

The difference between the upper page bit count and the lower page bit count is 30%. When the bit count difference exceeds, for example, 20%, the control unit 22 determines that the data is incompletely written data.

Next, at the time of writing completion, both the upper page bit count and the lower page bit count are 50% (area EA13). The difference between the upper page bit count and the lower page bit count is 0%. Since the difference in bit count does not exceed, for example, 20%, the control unit 22 determines that the data is completely written data.

As described above, according to the memory system of the third embodiment, it is determined whether the data is incompletely written data based on the bit count value from the start to the completion of the writing to the upper page and the lower page.

Accordingly, it is possible to prevent erroneous determination when data writing is not completed. In addition, it is possible to reduce the amount of processing by not performing the retry reading of the incomplete write data. In addition, even for the normal write data, it is possible to avoid an extra read by the assigned check, and it is possible to reduce the amount of processing.

According to the memory system of at least one embodiment described above, when the data is read, the number of bits set to 1 or 0 included in the data is counted and the bit count value is output. If the error checking and correction code decoding error occurs in the read data, it is determined whether the data is completely written based on the bit count value and the first reference value. If it is determined that the data is completely written, the retry reading of the written data is executed.

Accordingly, it is possible to reduce the amount of processing by not performing the retry reading if data writing is incomplete. In addition, even when the data writing is completed, it is possible to avoid an extra read by the assigned check, and it is possible to reduce the amount of processing.

For the memory systems according to the first to third embodiments, the description has been given on the case where TLC writing is performed on a plurality of pages. However, it is not limited thereto and even when the MLC writing is performed on a plurality of pages, the memory systems of the first to third embodiments are also applicable to the case described above.

In addition, the memory systems according to the first to third embodiments count the number of bits of 1. However, the memory system may count the number of bits of 0 and compare the bit count value of 0 with a reference value to determine whether the data is normally written data.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory reading method comprising:
reading data from a memory cell array of a nonvolatile memory where data is written after randomization, using a first read voltage;
counting a total number of bits set to either 1 or 0 in the read data;
performing an error correction on the read data; and
in case of failure of the error correction, retrying reading the data using a second read voltage only when the counted total number of bits falls within a first predetermined range.

2. The memory reading method according to claim 1, further comprising:
after the retry of the reading, performing an error correction on the read data.

3. The memory reading method according to claim 2, further comprising:
in case of success of the error correction after the retry of the reading, outputting a signal indicating the success of the error correction.

4. The memory reading method according to claim 2, further comprising:
in case of failure of the error correction after the retry of the reading, outputting a signal indicating the failure of the error correction.

5. The memory reading method according to claim 1, wherein
the memory cell array includes a plurality of pages each formed by a plurality of triple level cells sharing a word line, and
the method further comprises:
in case of failure of the error correction, before retrying the reading using the second read voltage, further reading the data using the first read voltage when the counted total number of bits in one of the pages falls within the first predetermined range and an elapsed time since start of writing the data to the memory cell array does not exceed a predetermined time.

6. The memory reading method according to claim 5, further comprising:
after further reading the data, counting a total number of bits set to 0 in the read data, wherein
when the counted total number of bits set to 0 exceeds a predetermined value, the retry of the reading is performed.

7. The memory reading method according to claim 6, wherein
after the retry of the reading, performing an error correction on the read data, and in case of failure of the error correction, outputting a signal indicating the failure of the error correction.

8. The memory reading method according to claim 1, wherein
the error correction is performed by an Error Correction Code (ECC) circuit.

9. The memory reading method according to claim 1, wherein
the memory cell array is formed by a plurality of single level cells.

10. The memory reading method according to claim 1, wherein
the total number of bits are counted by a counter circuit arranged in a memory device.

11. A memory system comprising:
a nonvolatile memory comprising a memory cell array where data is written after randomization;
a controller configured to read data from the memory cell array using a first read voltage; and
a counter circuit configured to count a total number of bits set to either 1 or 0 in the read data, wherein
the controller is further configured to
perform an error correction on the read data, and
in case of failure of the error correction, retry reading the data using a second read voltage only when the counted total number of bits falls within a first predetermined range.

12. The memory system according to claim 11, wherein
after the retry of the reading, the controller performs an error correction on the read data.

13. The memory system according to claim 12, wherein
in case of success of the error correction after the retry of the reading, the controller outputs a signal indicating the success of the error correction.

14. The memory system according to claim 12, further comprising:
in case of failure of the error correction after the retry of the reading, outputting a signal indicating the failure of the error correction.

15. The memory system according to claim 11, wherein
the memory cell array includes a plurality of pages each formed by a plurality of triple level cells sharing a word line, and
in case of failure of the error correction, before retrying the reading using the second read voltage, the controller further reads the data using the first read voltage when the counted total number of bits in one of the pages falls within the first predetermined range and an elapsed time since start of writing the data to the memory cell array does not exceed a predetermined time.

16. The memory system according to claim 15, wherein
after further reading the data, the controller counts a total number of bits set to 0 in the read data, and
when the counted total number of bits set to 0 exceeds a predetermined value, the controller performs the retry of the reading.

17. The memory system according to claim 15, wherein
after the retry of the reading, the controller performs an error correction on the read data, and in case of failure of the error correction, outputs a signal indicating the failure of the error correction.

18. The memory system according to claim 11, wherein
the controller comprises an ECC circuit configured to perform the error correction.

19. The memory system according to claim 11, wherein
the nonvolatile memory and the counter circuit are arranged in a memory device connected to the controller.

20. A non-transitory computer readable medium storing a program causing a computer to execute a method comprising:
reading data from a memory cell array of a nonvolatile memory where data is written after randomization, using a first read voltage;
counting a total number of bits set to either 1 or 0 in the read data;
performing an error correction on the read data; and
in case of failure of the error correction, retrying reading the data using a second read voltage only when the counted total number of bits falls within a first predetermined range.
